(19) United States
(12) Patent Application Publication
(10) Pub. No.: US 2015/0234478 A1
(43) Pub. Date: Aug. 20, 2015

(54) Mobile Device Application State

(71) Applicant: Microsoft Technology Licensing, LLC, Redmond, WA (US)

(72) Inventors: Jim Tom Belesiu, Mill Creek, WA (US); Sharon Drasnin, Seattle, WA (US); Michael A. Schwager, Seattle, WA (US); Christopher Harry Stoumbos, Sammamish, WA (US); Mark J. Seilstad, Sammamish, WA (US)

(21) Appl. No.: 14/704,423

(22) Filed: May 5, 2015

Related U.S. Application Data
(63) Continuation of application No. 13/651,976, filed on Oct. 15, 2012, now Pat. No. 9,047,207.
Application No. 13/651,976 is a continuation of application No. 13/471,001, filed on May 14, 2012, now abandoned.
(60) Provisional application No. 61/606,321, filed on Mar. 2, 2012.
(60) Provisional application No. 61/606,321, filed on Mar. 2, 2012.
(60) Provisional application No. 61/606,313, filed on Mar. 2, 2012.
(60) Provisional application No. 61/606,333, filed on Mar. 2, 2012.
(60) Provisional application No. 61/613,745, filed on Mar. 21, 2012.
(60) Provisional application No. 61/606,336, filed on Mar. 2, 2012.
(60) Provisional application No. 61/607,451, filed on Mar. 6, 2012.

(51) Int. Cl. G06F 3/023; G01P 15/00; G06F 1/32; G06F 3/00; G06F 3/02; G06F 1/16; G01B 21/22; G01R 21/00

(52) U.S. Cl. CPC G06F 3/023; G01B 21/22; G01P 15/00; G01R 21/00; G06F 3/002; G06F 3/0202; G06F 1/1618; G06F 1/1677; G06F 1/1656; G06F 1/3265

(57) ABSTRACT

Techniques for mobile device application state are described. In one or more implementations, a mobile device includes a computing device that is flexibly coupled to an input device via a flexible hinge. Accordingly, the mobile device can operate in a variety of different power states based on a positional orientation of the computing device to an associated input device. In one or more implementations, an application that resides on a computing device can operate in different application states based on a positional orientation of the computing device to an associated input device. In one or more implementations, techniques discussed herein can differentiate between vibrations caused by touch input to a touch functionality, and other types of vibrations. Based on this differentiation, techniques can determine whether to transition between device power states.

### RELATED APPLICATIONS

This application is a continuation of and claims priority to U.S. patent application Ser. No. 13/651,976, filed Oct. 15, 2012, entitled “Mobile Device Power State” and further claims priority U.S. patent application Ser. No. 13/471,001, filed May 14, 2012, entitled “Mobile Device Power State” and further claims priority under 35 U.S.C. §119(e) to the following U.S. Provisional Patent Applications, the entire disclosures of each of these applications being incorporated by reference in their entirety:

U.S. Provisional Patent Application No. 61/606,321, filed Mar. 2, 2012, Attorney Docket Number 336082.01, and titled “Screen Edge;”

U.S. Provisional Patent Application No. 61/606,301, filed Mar. 2, 2012, Attorney Docket Number 336083.01, and titled “Input Device Functionality;”

U.S. Provisional Patent Application No. 61/606,313, filed Mar. 2, 2012, Attorney Docket Number 336084.01, and titled “Functional Hinge;”

U.S. Provisional Patent Application No. 61/606,333, filed Mar. 2, 2012, Attorney Docket Number 336086.01, and titled “Usage and Authentication;”

U.S. Provisional Patent Application No. 61/613,745, filed Mar. 21, 2012, Attorney Docket Number 336086.02, and titled “Usage and Authentication;”

U.S. Provisional Patent Application No. 61/606,336, filed Mar. 2, 2012, Attorney Docket Number 336087.01, and titled “Kickstand and Camera;” and

U.S. Provisional Patent Application No. 61/607,451, filed Mar. 6, 2012, Attorney Docket Number 336143.01, and titled “Spanaway Provisional.”

### BACKGROUND

Mobile computing devices have been developed to increase the functionality that is made available to users in a mobile setting. For example, a user may interact with a mobile phone, tablet computer, or other mobile computing device to check email, surf the web, compose texts, interact with applications, and so on.

Because mobile computing devices are configured to be mobile, the devices typically include some type of battery that serves as a mobile source of power for the devices. A limitation associated with utilizing battery power is that a battery has a limited effective charge life. When a battery charge for a mobile computing device is depleted, the battery is recharged or replaced in order to maintain operability of the device. Thus, to extend battery usage life, managing power consumption of mobile computing devices is an important consideration.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Techniques for mobile device application state are described. In one or more implementations, a mobile device includes a computing device that is flexibly coupled to an input device via a flexible hinge. Accordingly, the mobile device can operate in a variety of different power states based on a positional orientation of the computing device to an associated input device. For example, the computing device and the input device can be positioned at different respective tilt angles. Techniques can determine a tilt angle between the computing device and the input device, and can determine a particular power state for the computing device and/or the input device based on the tilt angle. For example, different tilt angle ranges can correspond to different power states.

In one or more implementations, an application that resides on a computing device can operate in different application states based on a positional orientation of the computing device to an associated input device. For example, a particular functionality of an application can be enabled or disabled based on a tilt angle between the computing device and the input device. Thus, different tilt angle ranges can correspond to different application states.

In one or more implementations, techniques can cause a computing device to transition between power states in response to detected vibrations. For example, a vibration detection mechanism (e.g., an accelerometer) associated with a computing device in a low power mode can detect vibration of the computing device and/or of an input device coupled to the computing device. The vibration, for instance, may be caused by user input to a touch functionality of the computing device, such as a touch screen of the computing device, a track pad of a coupled input device, and so on. Alternatively, the vibration can be caused by some other contact with the computing device, such as a result of inadvertent bumping of the computing device by a user, vibration of a table or other surface on which the computing device is resting, and so on. Thus, techniques discussed herein can differentiate between vibrations caused by touch input to a touch functionality, and other types of vibrations. Based on this differentiation, techniques can determine whether to transition between device power states.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different instances in the description and the figures may indicate similar or identical items. Entities represented in the figures may be indicative of one or more entities and thus reference may be made interchangeably to single or plural forms of the entities in the discussion.

FIG. 1 is an illustration of an environment in an example implementation that is operable to employ the techniques described herein.

FIG. 2 depicts an example implementation of an input device of FIG. 1 as showing a flexible hinge in greater detail.

FIG. 3 depicts an example orientation of the input device in relation to the computing device in accordance with one or more embodiments.

FIG. 4 depicts an example orientation of the input device in relation to the computing device in accordance with one or more embodiments.

FIG. 5 depicts an example orientation of the input device in relation to the computing device in accordance with one or more embodiments.

FIG. 6 depicts an example orientation of the input device in relation to the computing device in accordance with one or more embodiments.

FIG. 7 depicts an example orientation of the input device in relation to the computing device in accordance with one or more embodiments.

FIG. 8 depicts an example orientation of the input device in relation to the computing device in accordance with one or more embodiments.

FIG. 9 depicts some example rotational orientations of the computing device in relation to the input device in accordance with one or more embodiments.

FIG. 10 is a flow diagram that describes steps in a method in accordance with one or more embodiments.

FIG. 11 is a flow diagram that describes steps in a method in accordance with one or more embodiments.

FIG. 12 is a flow diagram that describes steps in a method in accordance with one or more embodiments.

FIG. 13 illustrates an example system including various components of an example device that can be implemented as any type of computing device as described with reference to FIGS. 1-12 to implement embodiments of the techniques described herein.

### DETAILED DESCRIPTION

### Overview

Techniques for mobile device application state are described. In one or more implementations, a mobile device includes a computing device that is flexibly coupled to an input device via a flexible hinge. Examples of an input device include a keyboard, a touch pad, combinations of a keyboard and touch pad, and so on. The computing device includes a display device (e.g., a display surface) and has independent operability separate from the input device, such as for outputting content, receiving touch input, and so on. The input device thus provides a mechanism for providing input to the computing device, but the computing device is also operable to provide functionality independent of the input device.

In one or more implementations, a computing device can operate in a variety of different power states based on a positional orientation of the computing device to an associated input device. For example, the computing device and the input device can be positioned at different respective tilt angles. Techniques can determine a tilt angle between the computing device and the input device, and can determine a particular power state for the computing device and/or the input device based on the tilt angle. For example, different tilt angle ranges can correspond to different device power states.

In one or more implementations, an application that resides on a computing device can operate in different application states based on a positional orientation of the computing device to an associated input device. For example, a particular functionality of an application can be enabled or disabled based on a tilt angle between the computing device and the input device. Thus, different tilt angle ranges can correspond to different application states.

In one or more implementations, techniques can cause a computing device to transition between power states in response to detected vibrations. For example, a vibration detection mechanism (e.g., an accelerometer) associated with a computing device in a low power mode can detect vibration of the computing device and/or of an input device coupled to the computing device. The vibration, for instance, may be caused by user input to a touch functionality associated with the computing device, such as a touch screen of the computing device, a track pad of a coupled input device, and so on. Alternatively, the vibration can be caused by some other contact with the computing device, such as a result of inadvertent bumping of the computing device by a user, vibration of a table or other surface on which the computing device is resting, and so on.

In response to the detected vibration, techniques can query a functionality of the computing device to determine whether the vibration was caused by touch input from a user. For example, a capacitive touch input mechanism (e.g., a track pad, a touch screen, and so forth) can be powered on and queried to determine whether the mechanism is receiving touch input from a user. Touch input, for instance, can indicate intent from a user to cause the computing device to transition from a low power (e.g., sleep) mode, to a functional mode.

If the mechanism indicates that it is receiving touch input, the computing device can wake from the low power mode. Absent an indication of touch input, the computing device can remain in a low power state. Thus, techniques can utilize a sensing mechanism that consumes less power to detect vibration of a computing device, and can utilize a mechanism that consumes more power (e.g., a capacitive touch sensor) to ascertain whether the vibration resulted from touch input. This can enable a sensing mechanism that consumes more power to remain in a low power state (e.g., an off state) unless queried to confirm the presence of touch input, thus reducing power consumption by a computing device.

In the following discussion, an example environment is first described that may employ techniques described herein. Next, a section entitled “Example Device Orientations” describes some example mobile device orientations in accordance with one or more embodiments. Following this, example procedures are described which may be performed in the example environment as well as other environments. Consequently, performance of the example procedures is not limited to the example environment and the example environment is not limited to performance of the example procedures. Next, a section entitled “Touch Initiated Power State Transition” describes example embodiments for transitioning between power states based on touch input. Finally, an example system and device are described in which embodiments may be implemented in accordance with one or more embodiments. Further, although an input device is described, other devices are also contemplated that do not include input functionality, such as covers.

### Example Environment

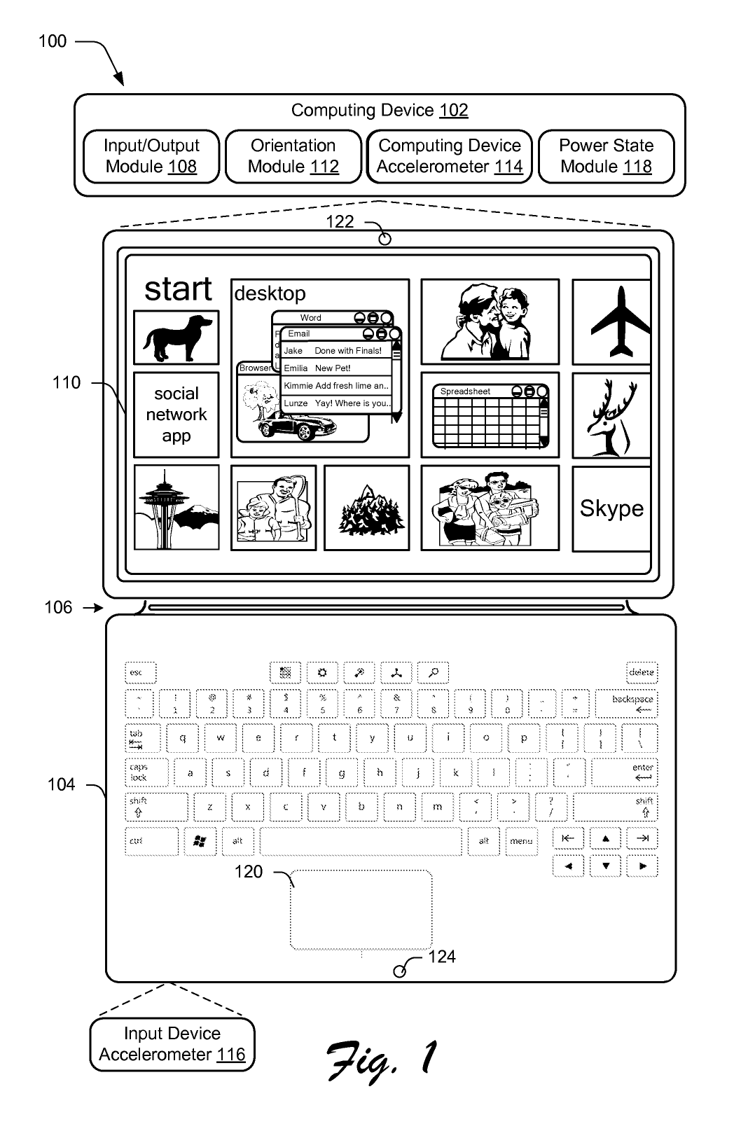

FIG. 1 is an illustration of an environment 100 in an example implementation that is operable to employ techniques described herein. The illustrated environment 100 includes an example of a computing device 102 that is physically and communicatively coupled to an input device 104 via a flexible hinge 106. The computing device 102 may be configured in a variety of ways. For example, the computing device 102 may be configured for mobile use, such as a mobile phone, a tablet computer as illustrated, and so on. Thus, the computing device 102 may range from full resource devices with substantial memory and processor resources to a low-resource device with limited memory and/or processing resources. The computing device 102 may also relate to software that causes the computing device 102 to perform one or more operations.

The computing device 102, for instance, is illustrated as including an input/output module 108. The input/output module 108 is representative of functionality relating to processing of inputs and rendering outputs of the computing device 102. A variety of different inputs may be processed by the input/output module 108, such as inputs relating to functions that correspond to keys of the input device 104, keys of a virtual keyboard displayed by a display device 110 to identify gestures and cause operations to be performed that correspond to the gestures that may be recognized through the input device 104 and/or touchscreen functionality of the display device 110, and so forth. Thus, the input/output module 108 may support a variety of different input techniques by recognizing and leveraging a division between types of inputs including key presses, gestures, and so on.

In the illustrated example, the input device 104 is configured as having an input portion that includes a keyboard having a QWERTY arrangement of keys and track pad although other arrangements of keys are also contemplated. Further, other non-conventional configurations are also contemplated, such as a game controller, configuration to mimic a musical instrument, and so forth. Thus, the input device 104 and keys incorporated by the input device 104 may assume a variety of different configurations to support a variety of different functionality.

As previously described, the input device 104 is physically and communicatively coupled to the computing device 102 in this example through use of a flexible hinge 106. The flexible hinge 106 is flexible in that rotational movement supported by the hinge is achieved through flexing (e.g., bending) of the material forming the hinge as opposed to mechanical rotation as supported by a pin, although that embodiment is also contemplated. Further, this flexible rotation may be configured to support movement in one or more directions (e.g., vertically in the figure) yet restrict movement in other directions, such as lateral movement of the input device 104 in relation to the computing device 102. This may be used to support consistent alignment of the input device 104 in relation to the computing device 102, such as to align sensors used to change power states, application states, and so on.

The flexible hinge 106, for instance, may be formed using one or more layers of fabric and include conductors formed as flexible traces to communicatively couple the input device 104 to the computing device 102 and vice versa. This communication, for instance, may be used to communicate a result of a key press to the computing device 102, receive power from the computing device, perform authentication, provide supplemental power to the computing device 102, and so on. The flexible hinge 106 may be configured in a variety of ways, further discussion of which may be found in relation to the figures discussed below.

The computing device 102 further includes an orientation module 112, which is representative of functionality to determine a positional orientation of the computing device 102 relative to the input device 104. For example, the orientation module 112 can receive orientation information from a computing device accelerometer 114, and from an input device accelerometer 116. The orientation module 112 can utilize the orientation information from the respective accelerometers to determine a relative orientation of the devices. The relative orientation, for instance, can indicate an angle at which the computing device 102 (e.g., the display device 110) is tilted with reference to the input device 104. Orientation information can be leveraged to perform various tasks, such as determining an appropriate power state for the computing device 102 and/or the input device 104, determining application states for various applications, and so on.

A power state module 118 is included, which is representative of functionality to cause the computing device 102 and/or the input device 104 to operate in various power states. For example, based on different device orientations determined by the orientation module 112, the power state module 118 can power on, power off, and hibernate the computing device 102 and/or the input device 104. A variety of other power states are contemplated as well. Different tilt angle ranges, for instance, can be associated with different power states for the computing device 102 and/or the input device 104.

The power state module 118 may also be employed to cause the computing device 102 and/or the input device 104 to transition between power states based on detected vibration, such as detected via the computing device accelerometer 114 and/or the input device accelerometer 116. Such vibration can be caused by user contact with the computing device 102 and/or the input device 104. For example, a user can touch the display device 110 and/or a track pad 120 to initiate waking the computing device 102 and/or the input device 104 from a sleep mode. Vibration may also be caused by other forms of contact, such as a user bumping the device and/or a surface on which the device is situated. As discussed in detail below, techniques can be implemented to differentiate between wake events (e.g., a user touching a key and/or the track pad 120), and non-wake events, such as incidental contact with a device.

As referenced above, the computing device 102 can be rotated to assume different orientations with respect to the input device 104. For instance, the computing device 102 can be rotated to a closed position, where the input device 104 covers the display device 110. An example technique for detecting when the computing device is in a closed position utilizes a first sensing portion 122 and a second sensing portion 124. The first sensing portion 122 is positioned on a region of the computing device 102, such as underneath an external surface near the edge of the computing device 102. Similarly, the second sensing portion 124 can be positioned underneath an external surface near an edge of the input device 104. Together, the first sensing portion 122 and the second sensing portion 124 form a sensing mechanism that can detect when the computing device 102 is in a closed position.

The sensing mechanism, for instance, can leverage the Hall effect to utilize magnetic force to detect proximity between the computing device 102 and the input device 104. For example, the first sensing portion 122 can include a Hall effect sensor and the second sensing portion 124 can include a magnet. When the computing device 102 is rotated to a closed position, the first sensing portion 122 can align with the second sensing portion 124 such that the Hall effect sensor in the first sensing portion 122 detects the magnet in the second sensing portion 124. The first sensing portion 122 can indicate to various functionalities that the computing device 102 is in a closed position, such as to the orientation module 112, the power state module 118, and so forth. When the computing device 102 is positioned away from the input device 104, the first sensing portion 122 does not detect the second sensing portion 124. Thus, the first sensing portion 122 can indicate to various functionalities that the computing device 102 is in an open position.

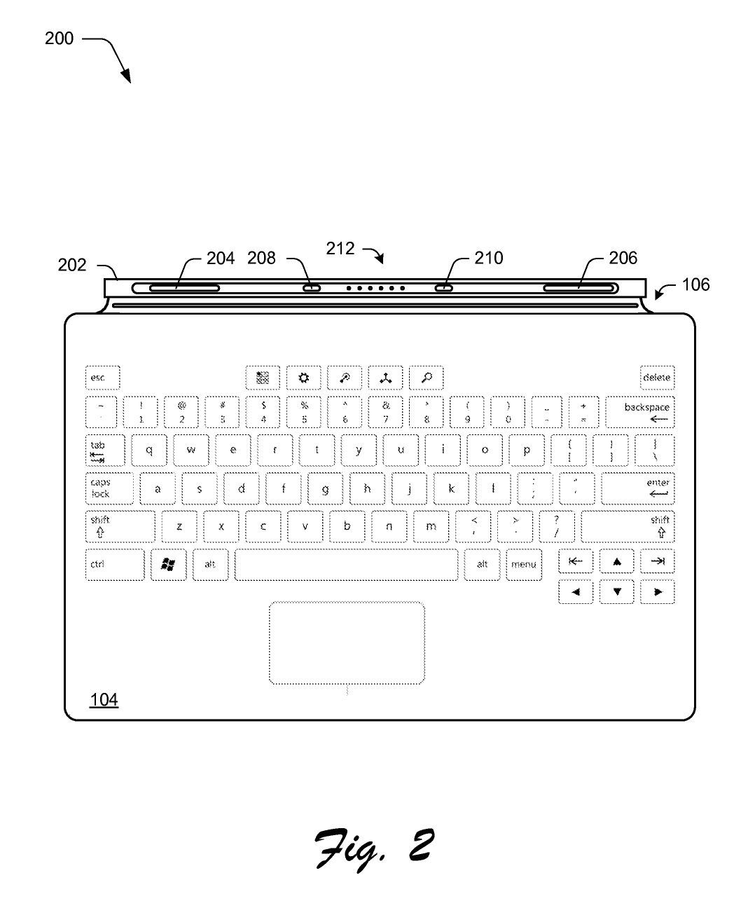

FIG. 2 depicts an example implementation 200 of the input device 104 of FIG. 1 as showing the flexible hinge 106 in greater detail. In this example, a connection portion 202 of the input device is shown that is configured to provide a communicative and physical connection between the input device 104 and the computing device 102. The connection portion 202 as illustrated has a height and cross section configured to be received in a channel in the housing of the computing device 102, although this arrangement may also be reversed without departing from the spirit and scope thereof.

The connection portion 202 is flexibly connected to a portion of the input device 104 that includes the keys through use of the flexible hinge 106. Thus, when the connection portion 202 is physically connected to the computing device the combination of the connection portion 202 and the flexible hinge 106 supports movement of the input device 104 in relation to the computing device 102 that is similar to a hinge of a book.

The connection portion 202 is illustrated in this example as including magnetic coupling devices 204, 206, mechanical coupling protrusions 208, 210, and communication contacts 212. The magnetic coupling devices 204, 206 are configured to magnetically couple to complementary magnetic coupling devices of the computing device 102 through use of one or more magnets. In this way, the input device 104 may be physically secured to the computing device 102 through use of magnetic attraction.

The connection portion 202 also includes mechanical coupling protrusions 208, 210 to form a mechanical physical connection between the input device 104 and the computing device 102. The communication contacts 212 are configured to contact corresponding communication contacts of the computing device 102 to form a communicative coupling between the devices as shown.

Having discussed an example environment in which embodiments may operate, consider now some example device orientations in accordance with one or more embodiments.

### Example Device Orientations

The following discussion presents some example device orientations. As detailed, different device orientations can be associated with different device power states, different application states, and so forth.

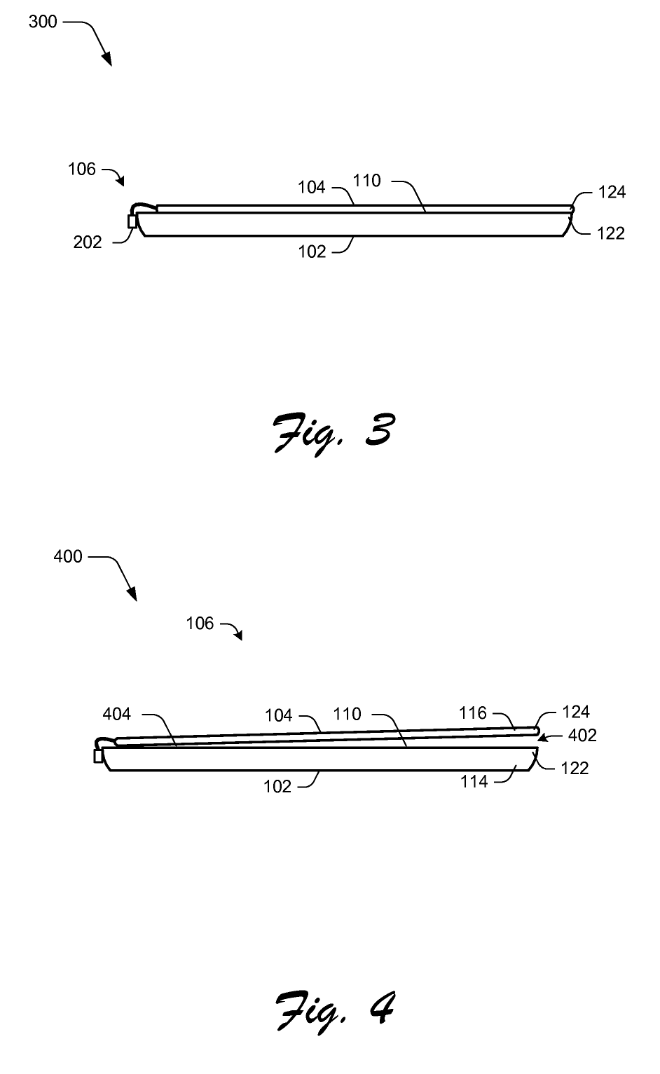

FIG. 3 illustrates that the input device 104 may be rotated such that the input device 104 is placed against the display device 110 of the computing device 102 to assume an orientation 300. In the orientation 300, the input device 104 may act as a cover such that the input device 104 can protect the display device 110 from harm. In implementations, the orientation 300 can correspond to a closed position of the computing device 102.

As referenced above, in a closed position the first sensing portion 122 can detect the proximity of the second sensing portion 124. Thus, the first sensing portion 122 can indicate to various functionalities that the computing device 102 is in a closed position. For example, the power state module 118 can determine that the computing device 102 is in a closed position, and can cause the computing device 102 to transition to a closed power state. In the closed power state, various functionalities can be powered off and/or hibernated, such as the input device 104, the display device 110, and so on.

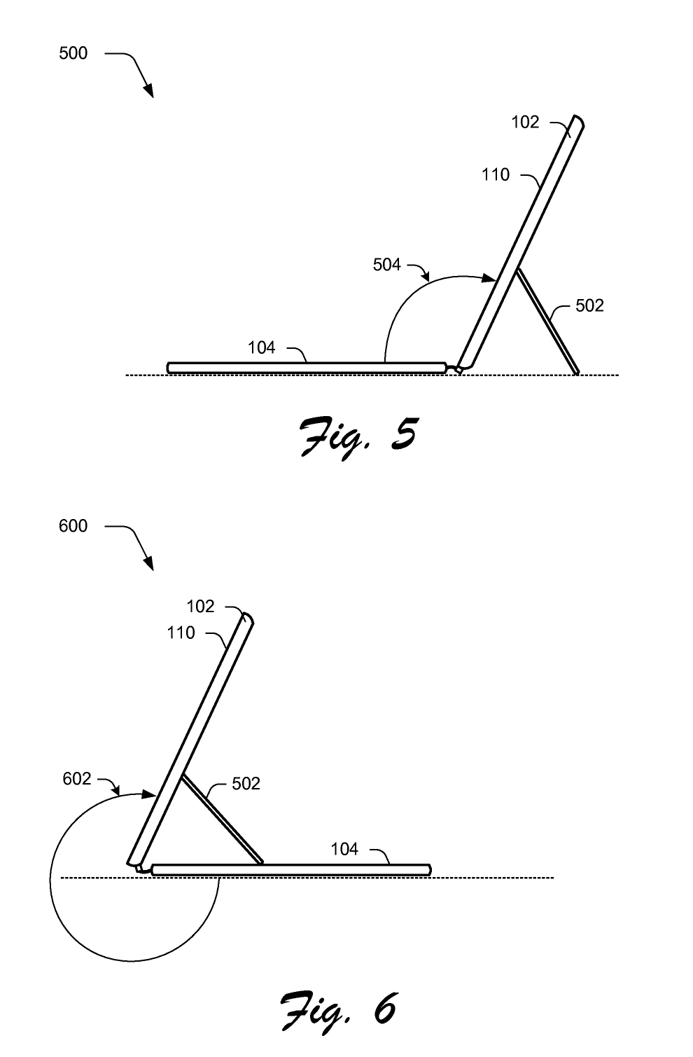

FIG. 4 illustrates that the input device 104 has rotated away from the computing device 102 such that the computing device assumes an orientation 400. The orientation 400 includes a gap 402 that is introduced between the computing device 102 and the input device 104. In implementations, the orientation 400 can be caused unintentionally by a user, such as by inadvertent contact with the computing device 102 and/or the input device 104 that causes the computing device 102 to sag slightly away from the input device 104 such that the gap 402 is introduced.

In at least some embodiments, in the orientation 400 the first sensing portion 122 may not detect the proximity of the second sensing portion 124. For example, the distance between the first sensing portion 122 and the second sensing portion 124 introduced by the gap 402 may be such that the first sensing portion 122 does not detect the second sensing portion 124.

When the computing device 102 is oriented at an angle relative to the input device 104, such as in the orientation 400, techniques can determine the angle. For example, the computing device accelerometer 114 can determine an angle at which the computing device 102 is oriented relative to earth's surface. Further, the input device accelerometer 116 can determine an angle at which the input device 104 is oriented relative to earth's surface. As detailed below, these two angles can be compared to determine an angle of orientation of the computing device 102 relative to the input device 104.

In the example illustrated in FIG. 4, the computing device 102 is oriented at an angle 404 relative to the input device 104. For example, the angle 404 can be determined to be approximately 4 degrees. While in the orientation 400 the computing device 102 has rotated slightly to the angle 404, the computing device 102 may nonetheless be considered to be in a closed position for purposes of determining an appropriate power state. The angle 404, for instance, may be considered to be within an angle range that corresponds to a closed position for the computing device 102. For example, an angle range of 0 degrees-30 degrees can correspond to a closed position. As mentioned above, a closed position can correspond to a closed power state in which various functionalities can be powered off and/or hibernated.

FIG. 5 illustrates an example orientation 500 of the computing device 102. In the orientation 500, the input device 104 is laid flat against a surface and the computing device 102 is disposed at an angle to permit viewing of the display device 110, e.g., such as through use of a kickstand 502 disposed on a rear surface of the computing device 102. The orientation 500 can correspond to a typing arrangement whereby input can be received via the input device 104, such as using keys of the keyboard, the track pad 120, and so forth.

Further to the example illustrated in FIG. 5, the computing device 102 is oriented at an angle 504 relative to the input device 104. For example, the angle 504 can be determined to be approximately 115 degrees. The angle 504 may be considered to be within an angle range that corresponds to a typing position for the computing device 102. For example, an angle range of 31 degrees-180 degrees can correspond to a typing position. Within this angle range, the computing device 102 and/or the input device 104 can placed in a typing power state. In the typing power state, the input device 104 and the computing device 102 can be powered on, such that input can be provided to the computing device 102 via the input device 104.

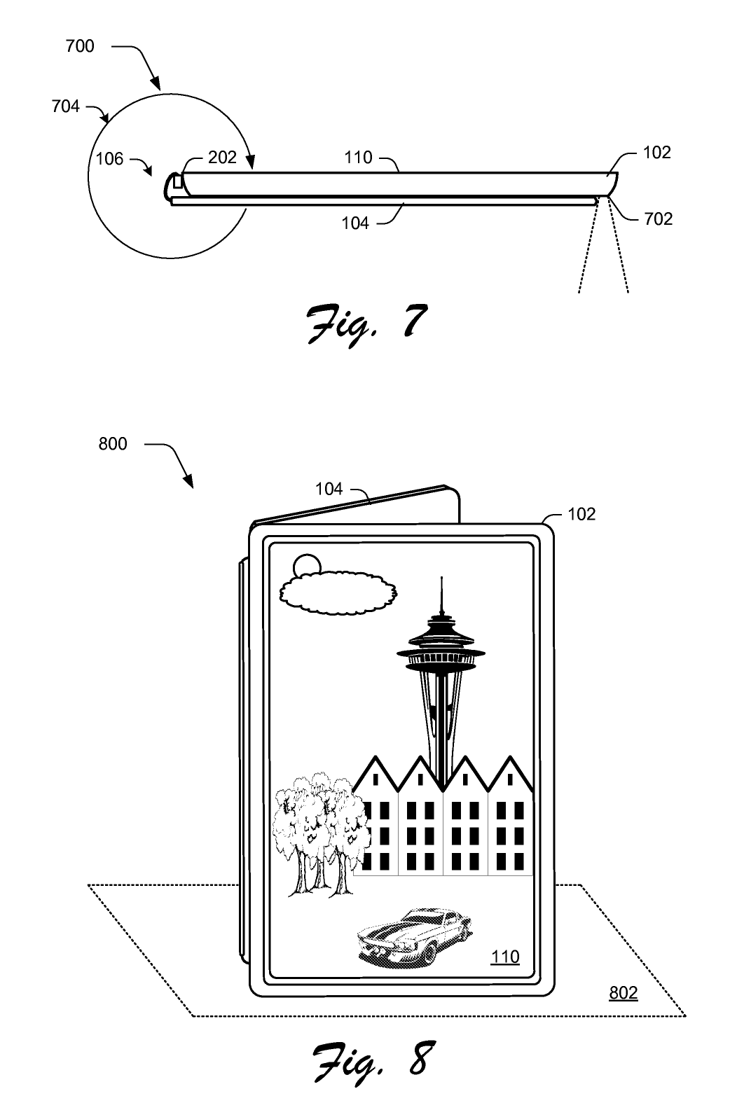

FIG. 6 illustrates a further example orientation of the computing device 102, generally at 600. In the orientation 600, the computing device 102 is oriented such that the display device 110 faces away from the input device 104. In this example, the kickstand 502 can support the computing device 102, such as via contact with a back surface of the input device 104. Although not expressly illustrated here, a cover can be employed to cover and protect a front surface of the input device 104.

Further to the example illustrated in FIG. 6, the display device 110 of the computing device 102 is determined to be oriented at an angle 602 relative to the input device 104. For example, the angle 602 can be determined to be approximately 295 degrees. The angle 602 may be considered to be within an angle range that corresponds to a viewing position for the computing device 102. For example, an angle range of 200 degrees-360 degrees can correspond to a viewing position. The orientation 600 can enable easy access to and/or viewing of the display device 110, such as for viewing content, providing touch input to the computing device 102, and so forth.

Within this angle range, the computing device 102 and/or the input device 104 can placed in a viewing power state. In the viewing power state, the computing device 102 can be powered on, and the input device 104 can be powered off or hibernated. Thus, battery power that would be used to power the input device 104 can be conserved, while enabling interaction and/or viewing of the display device 110 of the computing device 102.

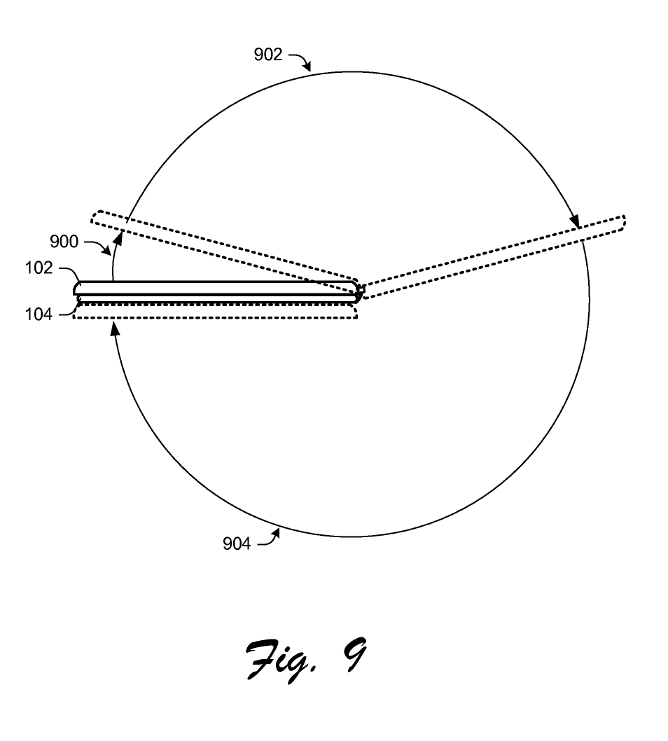

FIG. 7 illustrates an example orientation 700, in which the input device 104 may also be rotated so as to be disposed against a back of the computing device 102, e.g., against a rear housing of the computing device 102 that is disposed opposite the display device 110 on the computing device 102. In this example, through orientation of the connection portion 202 to the computing device 102, the flexible hinge 106 is caused to “wrap around” the connection portion 202 to position the input device 104 at the rear of the computing device 102.

This wrapping causes a portion of a rear of the computing device 102 to remain exposed. This may be leveraged for a variety of functionality, such as to permit a camera 702 positioned on the rear of the computing device 102 to be used even though a significant portion of the rear of the computing device 102 is covered by the input device 104 in the example orientation 700.

Further to the example illustrated in FIG. 7, the display device 110 of the computing device 102 is determined to be oriented at an angle 704 relative to the input device 104. For example, the angle 704 can be determined to be approximately 360 degrees. The angle 704, for instance, may be considered to be within the angle range (referenced above) that corresponds to a viewing position such that the computing device 102 is in a viewing power state. As referenced above, a viewing power state can enable viewing of and/or interaction with the display device 110, while powering off or hibernating the input device 104. In the viewing power state, the camera 702 can be powered on such that photos can be captured while the computing device is in the viewing power state.

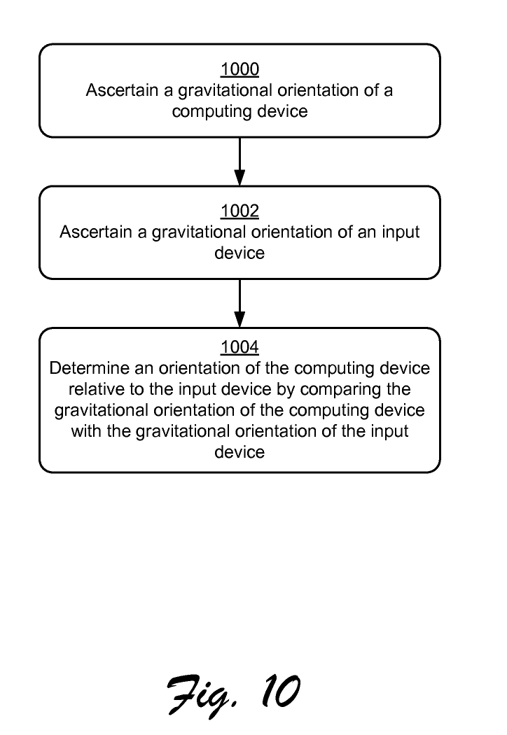

FIG. 8 illustrates a further example orientation of the computing device 102, generally at 800. In the orientation 800, the computing device 102 is rotated sideways, e.g., in a portrait orientation relative to a surface 802 on which the computing device 102 is disposed. The display device 110 is visible, with the input device 104 rotated away from the display device 110. In at least some implementations, a width of the input device 104 can be narrower than a width of the computing device 102. Additionally or alternatively, the width of the input device 104 can be tapered such that the edge closest to the hinge 106 is wider than the outermost edge. This can enable the face of the display device 110 to recline back in the orientation 800, to provide for a suitable viewing angle.

Further to the example illustrated in FIG. 8, techniques discussed herein can determine that the computing device 102 is disposed in the orientation 800. For example, the computing device accelerometer 114 and/or the input device accelerometer 116 can determine that the computing device 102 and/or the input device 104 are rotated to the orientation 800. In the orientation 800, a screen orientation for the display device 110 can be rotated 90 degrees, e.g., to a portrait viewing mode. Further, the computing device 102 can be placed in a viewing power state. As referenced above, a viewing power state can enable viewing of and/or interaction with the display device 110, while powering off or hibernating the input device 104.

FIG. 9 illustrates that the computing device 102 may be rotated within a variety of different angle ranges with respect to the input device 104. As detailed herein, different angle ranges can be associated with different power states, different application states, and so on.

An angle range 900 is illustrated, which corresponds to a closed position for the computing device 102. Thus, if the computing device 102 is positioned at an angle within the angle range 900 relative to the input device 104, the computing device 102 can be determined to be in a closed position. As referenced above, a closed position can include an associated closed power state where various functionalities can be powered off and/or hibernated, such as the input device 104, the display device 110, and so on.

Further illustrated is an angle range 902, which corresponds to a typing orientation for the computing device 102. Thus, if the computing device 102 is positioned at an angle within the angle range 902 relative to the input device 104, the computing device 102 can be determined to be in a typing orientation. Within this orientation, the computing device 102 and/or the input device 104 can placed in a typing power state where the input device 104 and the computing device 102 can be powered on, such that input can be provided to the computing device 102 via the input device 104, touch input to the display device 100, and so forth.

FIG. 9 further illustrates an angle range 904, which corresponds to a viewing position for the computing device 102. Thus, if the computing device 102 is positioned at an angle within the angle range 904 relative to the input device 104, the computing device 102 can be determined to be in a viewing orientation. In this orientation, the computing device 102 and/or the input device 104 can placed in a viewing power state such that the computing device 102 can be powered on, and the input device 104 can be powered off or hibernated.

The orientations, angle ranges, power states, and so forth discussed above are presented for purposes of illustration only. It is contemplated that a wide variety of different orientations, power states, and angle ranges may be implemented within the spirit and scope of the claimed embodiments.

Having discussed some example device orientations, consider now some example procedures in accordance with one or more embodiments.

### Example Procedures

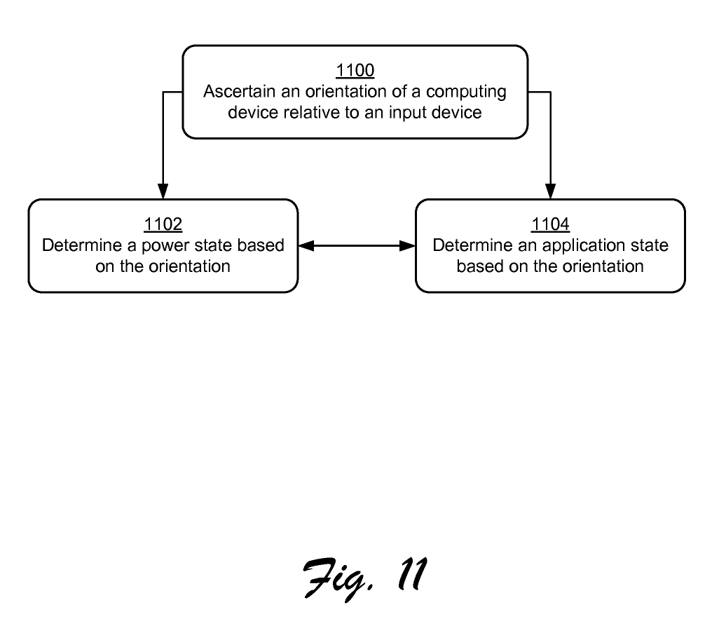

FIG. 10 is a flow diagram that describes steps in a method in accordance with one or more embodiments. In at least some embodiments, the method can be employed to determine an orientation of a computing device with respect to an input device.

Step 1000 ascertains a gravitational orientation of a computing device. For example, an orientation of the computing device accelerometer 114 relative to earth's gravity (e.g., the gravitational vector) can be determined. In implementations, this can include determining an angle at which an axis of the computing device accelerometer 114 is oriented with reference to earth's gravity.

Step 1002 ascertains a gravitational orientation of an input device. For example, an orientation of the input device accelerometer 116 relative to earth's gravity can be determined. In implementations, this can include determining an angle at which an axis of the input device accelerometer 116 is oriented with reference to earth's gravity.

Step 1004 determines an orientation of the computing device relative to the input device by comparing the gravitational orientation of the computing device with the gravitational orientation of the input device. For example, an angle at which the computing device is oriented relative to gravity can be compared to angle at which the input device is oriented relative to gravity, to determine an angle at which the computing device is oriented relative to the input device.

One example way of determining the orientation is as an angle θ (theta) between the computing device and the input device. θ can be determined using the equation

$$Θ = {cos}^{- 1} \frac{A \cdot B}{\vert A \vert \vert B \vert} ,$$

or the dot product divided by the product of the magnitudes, where A is the gravity vector of the computing device, and B is the gravity vector of the input device. This equation is presented for purpose of example only, and a wide variety of techniques can be employed to determine the orientation of the computing device relative to the input device within the spirit and scope of the claimed embodiments.

While techniques are discussed herein with respect to determining relative orientations using accelerometers, a variety of different techniques may be employed to determine orientations within the spirit and scope of the claimed embodiments.

FIG. 11 is a flow diagram that describes steps in a method in accordance with one or more embodiments. Step 1100 ascertains an orientation of a computing device relative to an input device. As discussed above, an orientation can include an angle at which a computing device is oriented with reference to an input device, and vice-versa.

Step 1102 determines a power state based on the orientation. For example, the power state can be determined for the computing device, the input device, and/or other devices that are operably associated with the computing device. Examples of different power states are discussed above.

Step 1104 determines an application state based on the orientation. For example, a particular functionality of an application can be enabled or disabled based on a particular orientation. In implementations, steps 1102 and 1104 can occur together, sequentially, alternatively, and so on.

The application state can be determined from a group of applications states that can be applied to the application while the application is running on the computing device. Thus, the application can include different operational states, at least some of which depend on device orientation. For example, consider a scenario including an application that enables a user to play a digital piano via a computing device. An input device that is operably attached to the computing device can include keys that can be pressed to play different musical notes of a piano. Thus, when the input device is disposed in an orientation in which input may be provided via the input device (e.g., the orientation 500 discussed above with reference to FIG. 5), the application can enable functionality to receive input from the input device to play musical notes.

When the input device is disposed in a different orientation, however, the application can disable functionality for receiving input from the input device. For instance, in the orientation 700 discussed above, the input device 104 is powered off or hibernated. Thus, in this orientation, the example application can disable functionality for receiving input via the input device 104. Further, the application can enable other functionality for receiving input, such as presenting visual piano keys that can be displayed via the display device 110 and that can receive touch input from a user for playing the digital piano.

As another example, the input device can be configured as a game controller. Thus, a game application can enable and disable particular game-related functionalities based on an orientation of the computing device and/or the input device.

### Touch Initiated Power State Transition

In at least some implementations, techniques enable transitions between power states in response to detected touch interactions. For example, vibrations that result from touch interaction can be detected to trigger certain events.

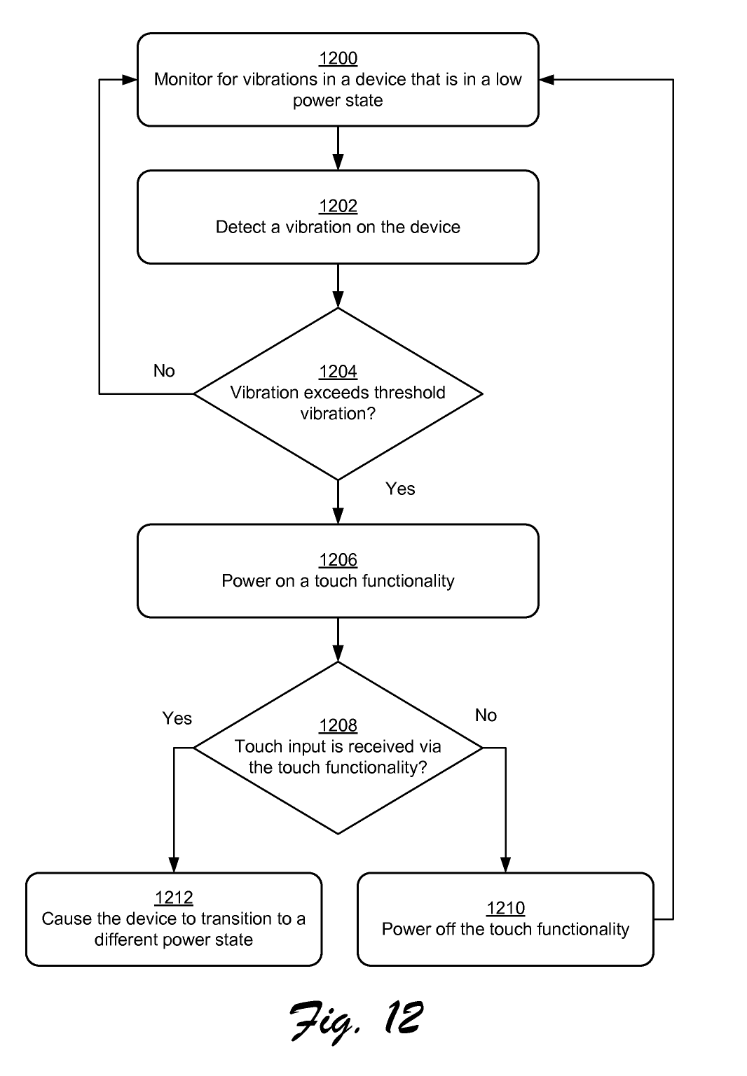

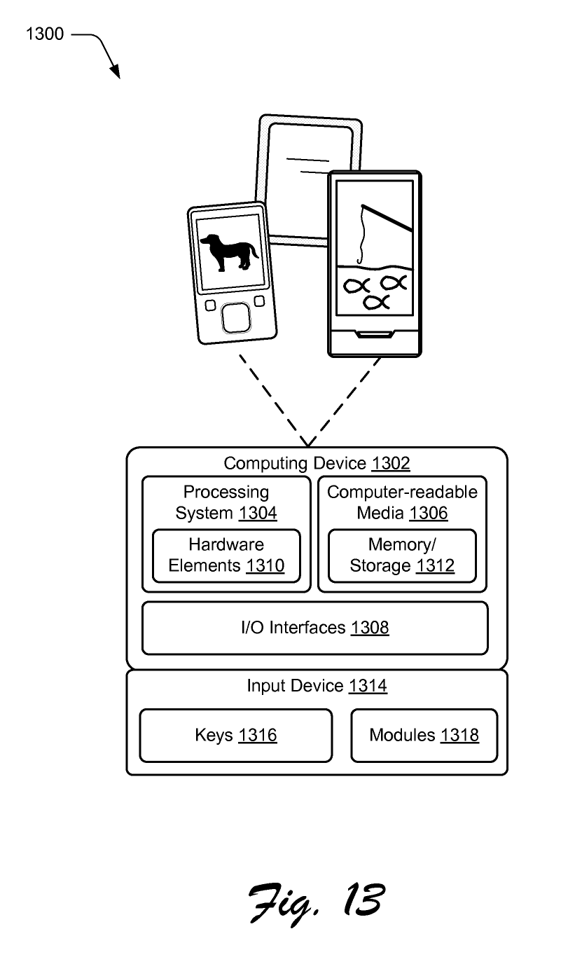

FIG. 12 is a flow diagram that describes steps in a method in accordance with one or more embodiments. Step 1200 monitors for vibrations in a device that is in a low power state. The monitoring, for instance, can occur in a low power state for the computing device 102 (e.g., a sleep mode) in which various functionalities are powered off and/or hibernated, such as the keyboard and track pad 120 of the input device 104, processors and/or the display device 110 of the computing device 102, and so forth. In the low power state, the computing device accelerometer 114 and/or the input device accelerometer 116 can be powered on to detect vibrations.

Step 1202 detects a vibration on the device. For example, the computing device accelerometer 114 and/or the input device accelerometer 116 can detect a vibration. As referenced above, a variety of different events can cause a device vibration. For instance, a user can provide touch input to a touch functionality to cause the device to wake from a low power mode. Alternatively, a vibration can be caused by other forms of contact with a device, such as a user bumping the device, a user bumping a surface on which the device is situated, and so on.

Step 1204 ascertains whether the vibration exceeds a vibration threshold. For example, a vibration threshold can be specified in terms of a suitable measurement, such as in meters per second squared (“g”), hertz (“Hz”), and so on. A vibration may be detected, for instance, as N number of zero-crossings and N+1 values greater than a threshold of the readings from an accelerometer within a certain amount of time T. For example, if the readings from the accelerometer are +1 g, then −1 g, and then +1 g within 5 ms, this may be considered a single bump or vibration event. These are examples only, and any specific value may be used according to the specific implementation.

If the vibration does not exceed the vibration threshold (“No”), the method returns to step 1200. If the vibration exceeds the vibration threshold (“Yes”), step 1206 powers on a touch functionality. A touch functionality, for instance, includes a functionality that is configured to receive touch input. Examples of a touch functionality include a track pad (e.g., the track pad 120), a touch screen (e.g., the display device 110), a capacitive touch device, a keyboard for the input device 104, and so on. In at least some implementations, an accelerometer that detects the vibration can notify a device processor, which can cause power to be supplied to the touch functionality. For example, prior to the vibration being detected, the touch functionality can be in a power off mode, such as a hibernation mode. Thus, in response to detecting the vibration, the touch functionality can be powered on.

Step 1208 determines whether touch input is received via the touch functionality. For example, the touch functionality can be queried to determine whether touch input is received. If touch input is not received (“No”), step 1210 powers off the touch functionality. For instance, if the touch functionality indicates that touch input is not received, the touch functionality can be powered off. As referenced above, a vibration can result from other forms of contact with a device besides touch input to an input functionality, such as a user accidentally bumping the device. In at least some implementations, the method can return to step 1200.

If touch input is received (“Yes”), step 1212 causes the device to transition to a different power state. For example, the device can transition from the low power state to a powered state. Examples of a powered state include the typing and viewing power states discussed above. Thus, the different power state can cause various functionalities to be powered on, such as processors of the computing device 102, the display device 110, the input device 104, and so on.

Thus, the method described in FIG. 12 can enable a touch functionality that consumes more power (e.g., a capacitive sensing functionality) to remain in a low power mode, while a functionality that consumes relatively less power can remain powered on to detect vibrations associated with a possible touch interaction. If a vibration is detected, the touch functionality can be powered on to determine whether the vibration was caused by touch input to the touch functionality, e.g., by a user that wishes to wake a device from a low power mode. Thus, a lower power functionality (e.g., an accelerometer) can be employed as a monitoring mechanism, and a functionality that consumes more power (e.g., a touch functionality) can be employed as a confirmation mechanism to determine whether a detected vibration is a result of touch input, or some other event.

### Example System and Device

FIG. 13 illustrates an example system generally at 1300 that includes an example computing device 1302 that is representative of one or more computing systems and/or devices that may implement the various techniques described herein. The computing device 1302 may be, for example, be configured to assume a mobile configuration through use of a housing formed and size to be grasped and carried by one or more hands of a user, illustrated examples of which include a mobile phone, mobile game and music device, and tablet computer although other examples are also contemplated.

The example computing device 1302 as illustrated includes a processing system 1304, one or more computer-readable media 1306, and one or more I/O interface 1308 that are communicatively coupled, one to another. Although not shown, the computing device 1302 may further include a system bus or other data and command transfer system that couples the various components, one to another. A system bus can include any one or combination of different bus structures, such as a memory bus or memory controller, a peripheral bus, a universal serial bus, and/or a processor or local bus that utilizes any of a variety of bus architectures. A variety of other examples are also contemplated, such as control and data lines.

The processing system 1304 is representative of functionality to perform one or more operations using hardware. Accordingly, the processing system 1304 is illustrated as including hardware element 1310 that may be configured as processors, functional blocks, and so forth. This may include implementation in hardware as an application specific integrated circuit or other logic device formed using one or more semiconductors. The hardware elements 1310 are not limited by the materials from which they are formed or the processing mechanisms employed therein. For example, processors may be comprised of semiconductor(s) and/or transistors (e.g., electronic integrated circuits (ICs)). In such a context, processor-executable instructions may be electronically-executable instructions.

The computer-readable storage media 1306 is illustrated as including memory/storage 1312. The memory/storage 1312 represents memory/storage capacity associated with one or more computer-readable media. The memory/storage component 1312 may include volatile media (such as random access memory (RAM)) and/or nonvolatile media (such as read only memory (ROM), Flash memory, optical disks, magnetic disks, and so forth). The memory/storage component 1312 may include fixed media (e.g., RAM, ROM, a fixed hard drive, and so on) as well as removable media (e.g., Flash memory, a removable hard drive, an optical disc, and so forth). The computer-readable media 1306 may be configured in a variety of other ways as further described below.

Input/output interface(s) 1308 are representative of functionality to allow a user to enter commands and information to computing device 1302, and also allow information to be presented to the user and/or other components or devices using various input/output devices. Examples of input devices include a keyboard, a cursor control device (e.g., a mouse), a microphone, a scanner, touch functionality (e.g., capacitive or other sensors that are configured to detect physical touch), a camera (e.g., which may employ visible or non-visible wavelengths such as infrared frequencies to recognize movement as gestures that do not involve touch), and so forth. Examples of output devices include a display device (e.g., a monitor or projector), speakers, a printer, a network card, tactile-response device, and so forth. Thus, the computing device 1302 may be configured in a variety of ways to support user interaction.

The computing device 1302 is further illustrated as being communicatively and physically coupled to an input device 1314 that is physically and communicatively removable from the computing device 1302. In this way, a variety of different input devices may be coupled to the computing device 1302 having a wide variety of configurations to support a wide variety of functionality. In this example, the input device 1314 includes one or more keys 1316, which may be configured as pressure sensitive keys, mechanically switched keys, and so forth.

The input device 1314 is further illustrated as include one or more modules 1318 that may be configured to support a variety of functionality. The one or more modules 1318, for instance, may be configured to process analog and/or digital signals received from the keys 1316 to determine whether a keystroke was intended, determine whether an input is indicative of resting pressure, support authentication of the input device 1314 for operation with the computing device 1302, and so on.

Various techniques may be described herein in the general context of software, hardware elements, or program modules. Generally, such modules include routines, programs, objects, elements, components, data structures, and so forth that perform particular tasks or implement particular abstract data types. The terms “module,” “functionality,” and “component” as used herein generally represent software, firmware, hardware, or a combination thereof The features of the techniques described herein are platform-independent, meaning that the techniques may be implemented on a variety of commercial computing platforms having a variety of processors.

Techniques may further be implemented in a network environment, such as utilizing various cloud-based resources. For instance, methods, procedures, and so forth discussed above may leverage network resources to enable various functionalities.

An implementation of the described modules and techniques may be stored on or transmitted across some form of computer-readable media. The computer-readable media may include a variety of media that may be accessed by the computing device 1302. By way of example, and not limitation, computer-readable media may include “computer-readable storage media” and “computer-readable signal media.”

“Computer-readable storage media” may refer to media and/or devices that enable persistent and/or non-transitory storage of information in contrast to mere signal transmission, carrier waves, or signals per se. Thus, computer-readable storage media refers to non-signal bearing media. The computer-readable storage media includes hardware such as volatile and non-volatile, removable and non-removable media and/or storage devices implemented in a method or technology suitable for storage of information such as computer readable instructions, data structures, program modules, logic elements/circuits, or other data. Examples of computer-readable storage media may include, but are not limited to, RAM, ROM, EEPROM, flash memory or other memory technology, CD-ROM, digital versatile disks (DVD) or other optical storage, hard disks, magnetic cassettes, magnetic tape, magnetic disk storage or other magnetic storage devices, or other storage device, tangible media, or article of manufacture suitable to store the desired information and which may be accessed by a computer.

“Computer-readable signal media” may refer to a signal-bearing medium that is configured to transmit instructions to the hardware of the computing device 1302, such as via a network. Signal media typically may embody computer readable instructions, data structures, program modules, or other data in a modulated data signal, such as carrier waves, data signals, or other transport mechanism. Signal media also include any information delivery media. The term “modulated data signal” means a signal that has one or more of its characteristics set or changed in such a manner as to encode information in the signal. By way of example, and not limitation, communication media include wired media such as a wired network or direct-wired connection, and wireless media such as acoustic, RF, infrared, and other wireless media.

As previously described, hardware elements 1310 and computer-readable media 1306 are representative of modules, programmable device logic and/or fixed device logic implemented in a hardware form that may be employed in some embodiments to implement at least some aspects of the techniques described herein, such as to perform one or more instructions. Hardware may include components of an integrated circuit or on-chip system, an application-specific integrated circuit (ASIC), a field-programmable gate array (FPGA), a complex programmable logic device (CPLD), and other implementations in silicon or other hardware. In this context, hardware may operate as a processing device that performs program tasks defined by instructions and/or logic embodied by the hardware as well as a hardware utilized to store instructions for execution, e.g., the computer-readable storage media described previously.

Combinations of the foregoing may also be employed to implement various techniques described herein. Accordingly, software, hardware, or executable modules may be implemented as one or more instructions and/or logic embodied on some form of computer-readable storage media and/or by one or more hardware elements 1310. The computing device 1302 may be configured to implement particular instructions and/or functions corresponding to the software and/or hardware modules. Accordingly, implementation of a module that is executable by the computing device 1302 as software may be achieved at least partially in hardware, e.g., through use of computer-readable storage media and/or hardware elements 1310 of the processing system 1304. The instructions and/or functions may be executable/operable by one or more articles of manufacture (for example, one or more computing devices 1302 and/or processing systems 1304) to implement techniques, modules, and examples described herein.

Discussed herein are a number of methods that may be implemented to perform techniques discussed herein. Aspects of the methods may be implemented in hardware, firmware, or software, or a combination thereof The methods are shown as a set of blocks that specify operations performed by one or more devices and are not necessarily limited to the orders shown for performing the operations by the respective blocks. Further, an operation shown with respect to a particular method may be combined and/or interchanged with an operation of a different method in accordance with one or more implementations. Aspects of the methods can be implemented via interaction between various entities discussed above with reference to the environment 100.

### Conclusion

Although the example implementations have been described in language specific to structural features and/or methodological acts, it is to be understood that the implementations defined in the appended claims is not necessarily limited to the specific features or acts described. Rather, the specific features and acts are disclosed as example forms of implementing the claimed features.

What is claimed is:

1. A computer-implemented method comprising:
receiving an indication of a change in orientation of an input device relative to a computing device to which the input device is communicatively coupled; and
determining, via the computing device and from multiple different orientation-based application states that are applicable to an application while the application is running on the computing device, an application state for the application based on the change in orientation, the orientation-based application states including two or more application states that each correspond to a different way of receiving input for controlling functionality of the application.

2. The computer-implemented method of claim 1, wherein receiving the indication of a change in orientation comprises receiving the indication from one or more of an accelerometer of the computing device or an accelerometer of the input device.

3. The computer-implemented method of claim 1, wherein receiving the indication of a change in orientation comprises receiving the indication from one or more of an accelerometer of the computing device and an accelerometer of the input device, wherein the accelerometer of the computing device and the accelerometer of the input device are capable of determining at least an angle at which the computing device and the input device are oriented relative to the earth's surface, respectively, and wherein the angle of the computing device and the angle of the input device relative to the earth's surface are compared, one to another, to determine an angle at which the input device is oriented with reference to the computing device.

4. The computer-implemented method of claim 1, further comprising enabling or disabling functionality of the application based on a tilt angle between the computing device and the input device.

5. The computer-implemented method of claim 1, wherein the change in orientation comprises a change in an angle at which the input device is rotated relative to the computing device, and wherein determining comprises correlating the change in the angle to one of multiple angle ranges that each correspond to a respective application state for the computing device.

6. The computer-implemented method of claim 1, wherein an orientation of the computing device relative to the input device following the change in orientation comprises a typing orientation, and wherein the application state comprises a typing application state in which a typing input may be provided to the application running on the computing device via the input device.

7. The computer-implemented method of claim 1, wherein the input device is configured as a game controller, and the application is a game application that can enable and disable functionality of the game application based on an orientation of the input device relative to the computing device.

8. The computer-implemented method of claim 1, wherein the input device is configured as a musical input device, and the application is a music application configured to enable a functionality to receive input from the input device to play musical notes when in a first orientation-based application state, and further configured to disable the functionality to receive input from the input device to play musical notes when in a second orientation-based application state.

9. The computer-implemented method of claim 1, further comprising determining a power state for one or more of the computing device or the input device based on the change in orientation.

10. A system comprising:
one or more processors; and
one or more computer readable media embodying computer readable instructions which are executable by the one or more processors to perform operations including:
ascertaining an orientation of an input device relative to a computing device based at least in part on an angle at which the input device is oriented with reference to the computing device; and
determining, based on the orientation of the computing device relative to the input device, an application state for an application from multiple different orientation-based application states that are applicable to the application while the application is running on the computing device.

11. The system of claim 10, wherein ascertaining the orientation of the input device relative to the computing device further comprises determining the angle at which the input device is oriented with reference to the computing device based on input received from one or more of an accelerometer of the computing device or an accelerometer of the input device.

12. The system of claim 10, wherein ascertaining the orientation of the input device relative to the computing device further comprises determining the angle at which the input device is oriented with reference to the computing device based on input received from one or more of an accelerometer of the computing device or an accelerometer of the input device, wherein the accelerometer of the computing device and the accelerometer of the input device are capable of determining at least an angle at which the computing device and the input device are oriented relative to the earth's surface, respectively, and wherein the angle of the computing device and the angle of the input device relative to the earth's surface are compared, one to another, to determine the angle at which the input device is oriented with reference to the computing device.

13. The system of claim 10, the operations further including enabling or disabling functionality of the application based on a tilt angle between the computing device and the input device.

14. The system of claim 10, wherein the orientation comprises an angle at which the computing device is rotated relative to the input device, and wherein the determining further comprises correlating the angle to one of multiple angle ranges that each correspond to a different respective application state for the computing device.

15. The system of claim 10, the operations further including determining a power state for one or more of the computing device, the input device, or other device that is operably associated with the computing device based on the change in orientation.

16. The system of claim 10, wherein the orientation of the computing device relative to the input device comprises a typing orientation, and wherein the application state comprises a typing application state in which a typing input may be provided to the application running on the computing device via the input device.

17. The system of claim 10, wherein the input device is configured as a game controller, and the application is a game application that can enable and disable functionality of the game application based on an orientation of the input device relative to the computing device.

18. A system comprising:
an input device comprising an input device accelerometer capable of determining at least an angle at which the input device is oriented relative to the earth's surface;
a computing device operably coupled to the input device, the computing device including:
a computing device accelerometer capable of determining at least an angle at which the computing device is oriented relative to the earth's surface;
an orientation module configured to determine a positional orientation of the computing device relative to the input device based at least in part on the angle of the input device relative to the earth's surface and the angle of the computing device relative to the earth's surface; and
a power state module configured to:
cause the computing device and the input device to operate in different power states, respectively, based on different positional orientations of the computing device relative to the input device; and
cause an application to operate in different application states based on different positional orientations of the computing device relative to the input device, the different application states determined from a group of application states that are applicable to the application while the application is running on the computing device.

19. The system of claim 18, wherein the power state module is further configured to enable or disable functionality of the application based on the positional orientation of the computing device relative to the input device.

20. The system of claim 18, wherein the power state module is further configured to correlate an angle associated with the positional orientation of the computing device relative to the input device to one of multiple angle ranges that each correspond to a respective application state for the computing device.
